(19) United States
(12) Patent Application Publication
(10) Pub. No.: US 2007/0013425 A1
(43) Pub. Date: Jan. 18, 2007

(54) Lower minimum retention voltage storage elements

(76) Inventors: James B. Burr, Foster City, CA (US); Robert P. Masleid, Monte Sereno, CA (US); Kleanthes G. Koniaris, Palo Alto, CA (US)

Correspondence Address: WAGNER, MURABITO & HAO LLP, Third Floor, Two North Market Street, San Jose, CA, 95113, US

(21) Appl. No.: 11/172,084

(22) Filed: Jun. 30, 2005

(51) Int. Cl. H03K 3/356

(52) U.S. Cl. 327/208

(57) ABSTRACT

The present invention relates to integrated circuit storage element topologies with reduced sensitivity to process mismatch. Such storage elements have lower minimum retention voltage that enables lower standby voltage and therefore lower standby leakage and standby power.

### BACKGROUND

Integrated circuits are utilized in a wide variety of applications. For example, integrated circuits are found within computer systems, mobile telephones, portable digital music players, and automobiles, to name a few. Integrated circuits usually contain static latch circuits, which are utilized to maintain a desired logical state (e.g., one or zero) based on an electrical input. However, as the components of integrated circuits are continually fabricated at ever-smaller sizes, some of the fabricated static latch circuits are unable to operate properly thereby rendering them substantially useless. Specifically, the inoperability can be caused when devices of those static latch circuits fail to match each other as they are expected. This is referred to as device mismatch. Additionally, defects and/or leakage currents within those static latch circuits can also cause them not to operate properly.

### SUMMARY

The present invention relates to integrated circuit storage element topologies with reduced sensitivity to process mismatch. Such storage elements have lower minimum retention voltage that enables lower standby voltage and therefore lower standby leakage and standby power.

### BRIEF DESCRIPTION OF THE DRAWINGS

FIG. 1A is a schematic of an exemplary storage element circuit in accordance with embodiments of the invention.

FIG. 1B is a schematic of a second exemplary storage element circuit in accordance with embodiments of the invention.

FIG. 1C is a schematic of a third exemplary storage element circuit in accordance with embodiments of the invention.

FIG. 1D is a schematic of a fourth exemplary storage element circuit in accordance with embodiments of the invention.

FIG. 1E is a schematic of a fifth exemplary storage element circuit in accordance with embodiments of the invention.

FIG. 1F is a schematic of a sixth exemplary storage element circuit in accordance with embodiments of the invention.

FIG. 1G is a schematic of a seventh exemplary storage element circuit in accordance with embodiments of the invention.

FIG. 1H is a schematic of an eighth exemplary storage element circuit in accordance with embodiments of the invention.

FIG. 1I is a schematic of an exemplary NAND gate circuit in accordance with embodiments of the invention.

FIG. 1J is a schematic of a second exemplary NAND gate circuit in accordance with embodiments of the invention.

FIG. 1K is a schematic of a third exemplary NAND gate circuit in accordance with embodiments of the invention.

FIG. 2 is a schematic of a ninth exemplary storage element circuit in accordance with embodiments of the invention.

FIG. 3 is a schematic of a tenth exemplary storage element circuit in accordance with embodiments of the invention.

FIG. 4 is a schematic of an eleventh exemplary storage element circuit in accordance with embodiments of the invention.

FIG. 5 is a schematic of a twelfth exemplary storage element circuit in accordance with embodiments of the invention.

FIG. 6 is a schematic of a thirteenth exemplary storage element circuit in accordance with embodiments of the invention.

FIG. 7 is a schematic of a fourteenth exemplary storage element circuit in accordance with embodiments of the invention.

FIG. 8 is a flowchart of an exemplary method in accordance with embodiments of the invention.

FIG. 9A illustrates an exemplary parallel redundancy replacement rule in accordance with embodiments of the invention.

FIG. 9B illustrates a second exemplary parallel redundancy replacement rule in accordance with embodiments of the invention.

FIG. 9C illustrates an exemplary series redundancy replacement rule in accordance with embodiments of the invention.

FIG. 9D illustrates a second exemplary series redundancy replacement rule in accordance with embodiments of the invention.

FIG. 9E illustrates an exemplary redundancy replacement rule in accordance with embodiments of the invention.

FIG. 9F illustrates a second exemplary redundancy replacement rule in accordance with embodiments of the invention.

FIG. 10A illustrates an exemplary gate redundancy replacement rule in accordance with embodiments of the invention.

FIG. 10B illustrates a second exemplary gate redundancy replacement rule in accordance with embodiments of the invention.

FIG. 10C illustrates a third exemplary gate redundancy replacement rule in accordance with embodiments of the invention.

FIG. 10D illustrates a fourth exemplary gate redundancy replacement rule in accordance with embodiments of the invention.

FIG. 10E illustrates a fifth exemplary gate redundancy replacement rule in accordance with embodiments of the invention.

FIG. 10F illustrates a sixth exemplary gate redundancy replacement rule in accordance with embodiments of the invention.

FIG. 10G illustrates a seventh exemplary gate redundancy replacement rule in accordance with embodiments of the invention.

FIG. 11 is a diagram of an exemplary latch circuit having a tolerant master portion and an intolerant slave portion in accordance with embodiments of the invention.

### DETAILED DESCRIPTION

Reference will now be made in detail to embodiments in accordance with the invention, examples of which are illustrated in the accompanying drawings. While the invention will be described in conjunction with embodiments, it will be understood that these embodiments are not intended to limit the invention. On the contrary, the invention is intended to cover alternatives, modifications and equivalents, which may be included within the scope of the invention as defined by the appended claims. Furthermore, in the following detailed description of embodiments in accordance with the invention, numerous specific details are set forth in order to provide a thorough understanding of the invention. However, it will be evident to one of ordinary skill in the art that the invention may be practiced without these specific details. In other instances, well known methods, procedures, components, and circuits have not been described in detail as not to unnecessarily obscure aspects of the invention.

Note that some embodiments in accordance with the invention involve integrated circuit storage elements that include one or more redundant elements. It is appreciated that one or more integrated circuit storage elements can be utilized as components of, but are not limited to, latch circuits, keeper circuits, SRAM (static random access memory) cells, to name a few. A redundant element in accordance with the invention can be, but is not limited to, the addition of one or more redundant transistors and/or one or more redundant logic gate circuits to a circuit. For example, a redundant element can include adding one or more transistors in series or in parallel within one or more logic gates that are part of a storage element (or loop), or by adding additional logic gates such as, but not limited to, inverters. It is noted that a redundant element can be added to one part of a circuit and not to another part of the circuit. Furthermore, a redundant element can be independently added to the N-type devices of a circuit or to the P-type devices of a circuit. Understand that by adding a redundant element to a circuit (e.g., a storage element), it can affect both the statistics and electrical behavior of that circuit. For example, by including a redundant element as part of a storage element circuit, it can statistically lower the minimum retention voltage (Vmin) of that storage element circuit.

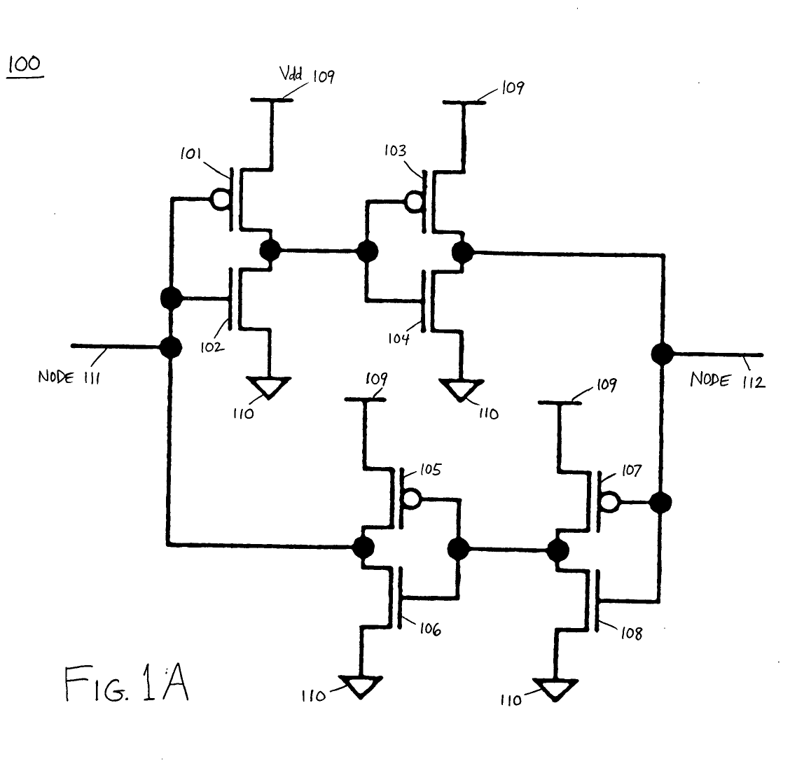

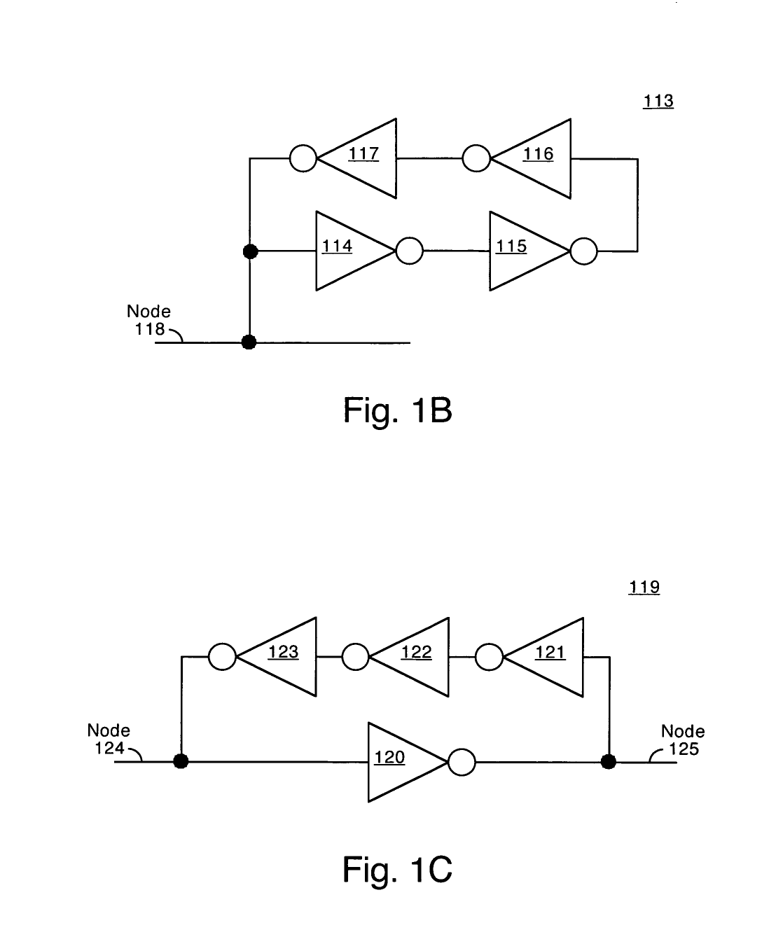

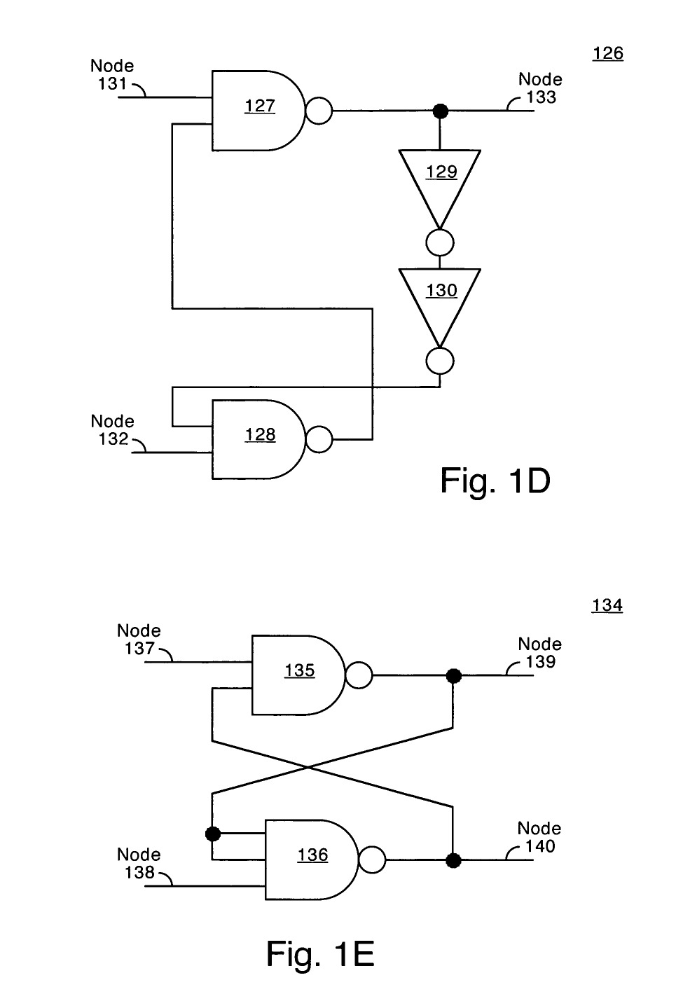

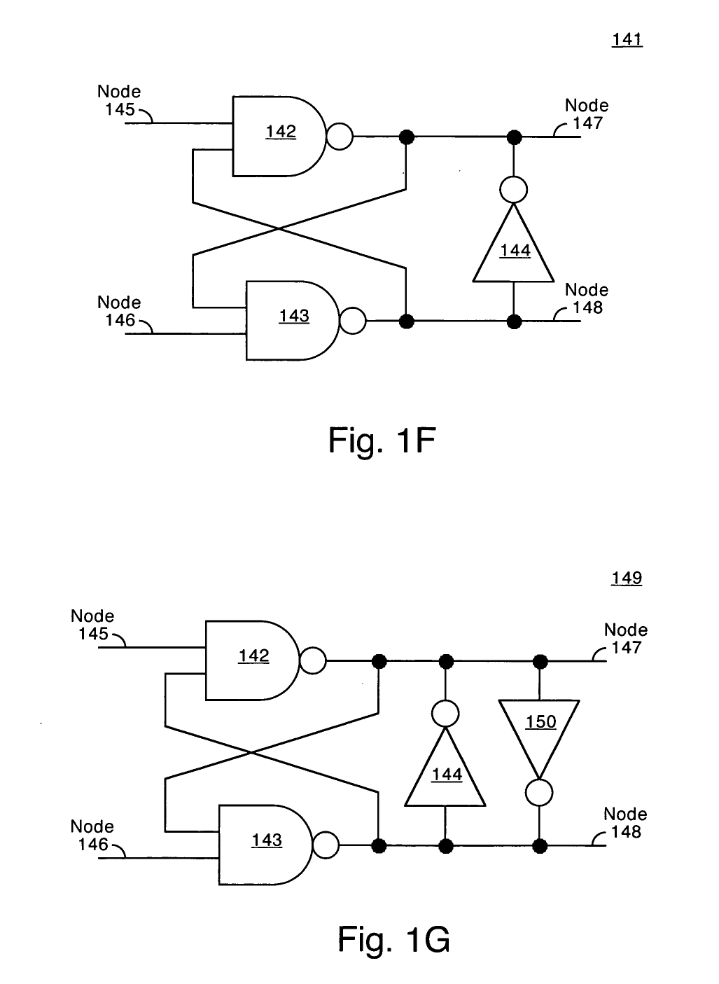

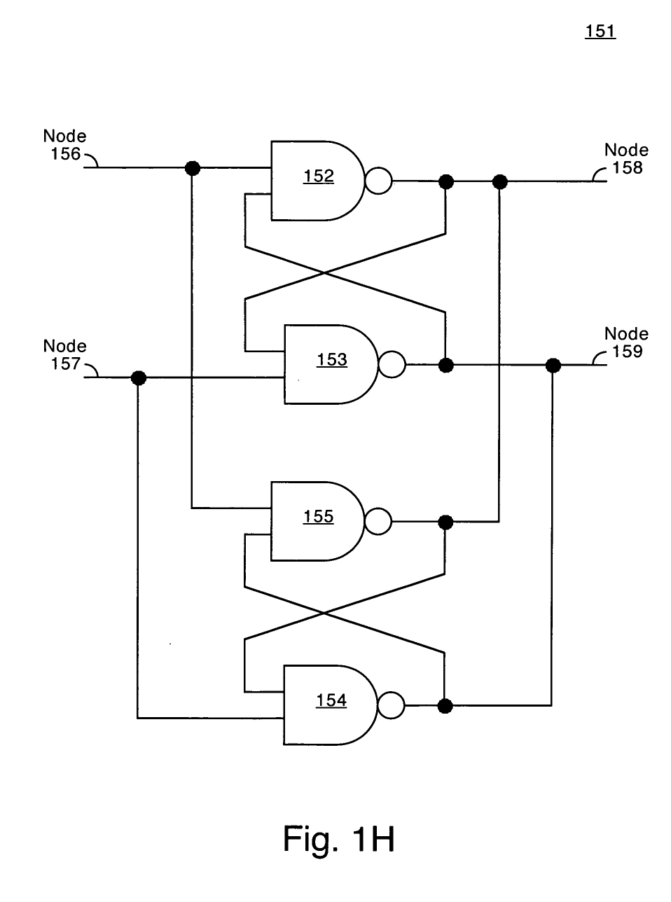

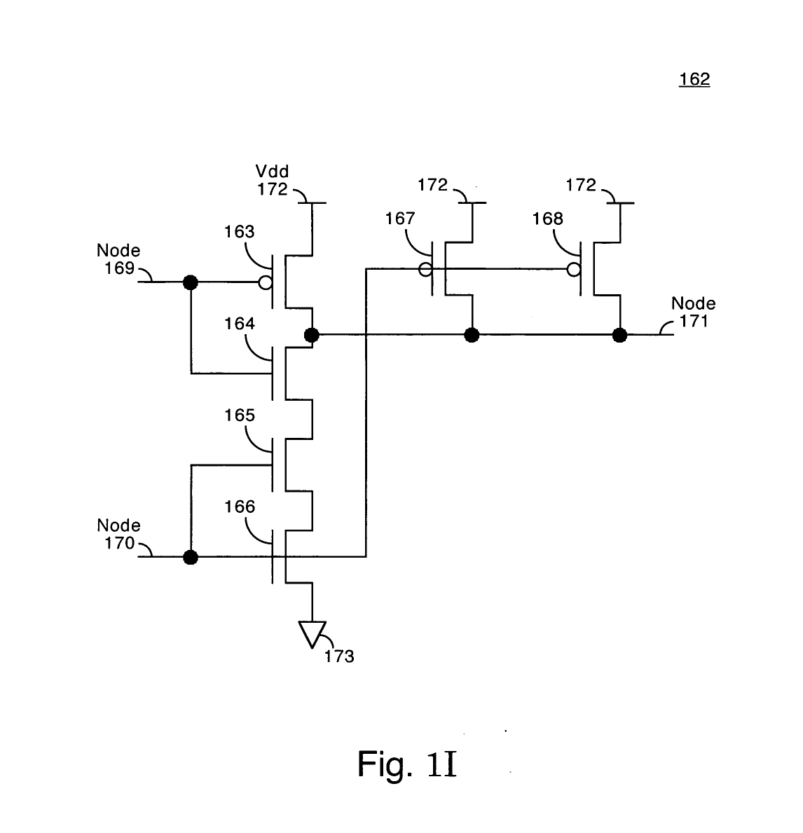

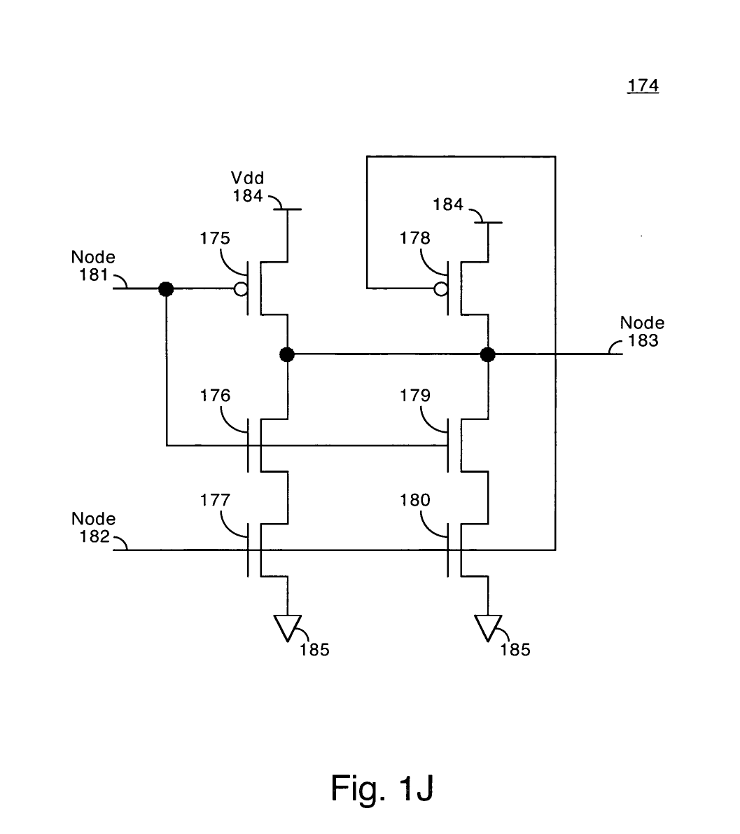

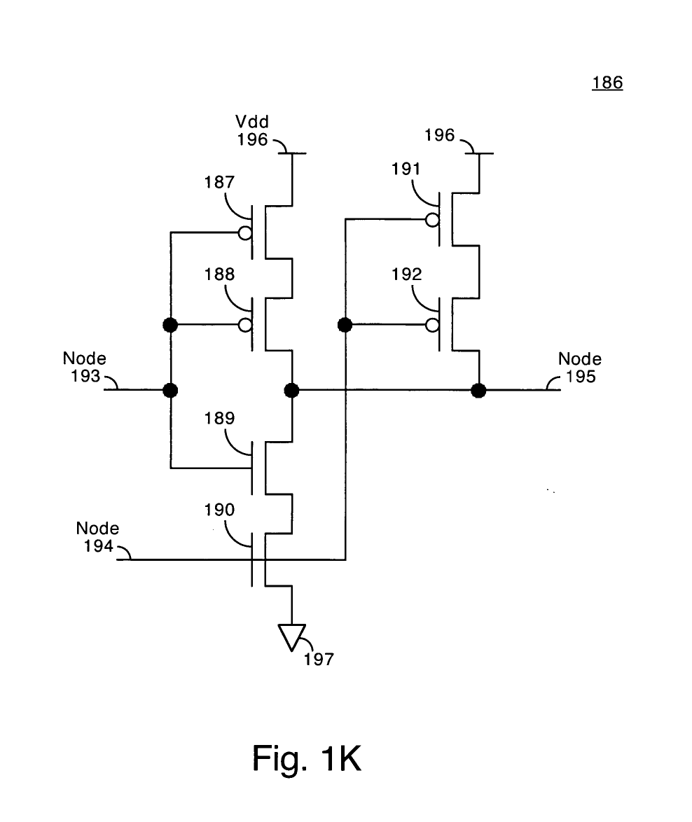

FIG. 1A is a schematic of an exemplary series quad inverter static storage element circuit 100 in accordance with embodiments of the invention. Storage element circuit 100 includes a positive feedback loop with four inverter circuits in sequential series. By including additional inverter circuits as part of storage element circuit 100, the threshold voltage (Vt) statistics of storage element circuit 100 are improved. The additional inverter circuits add more transistors to storage element circuit 100 over which to average the Vt and other statistics of its transistors for the purpose of statistically lowering the minimum retention voltage (Vmin) of storage element circuit 100. As such, storage element circuit 100 has a statistically lower sensitivity to transistor mismatch that can occur during its fabrication.

As previously mentioned above, storage element circuit 100 includes four inverter circuits coupled in sequential series. Specifically, a first inverter circuit of storage element circuit 100 can include transistors 101 and 102, a second inverter circuit can include transistors 103 and 104, a third inverter circuit can include transistors 105 and 106, and a fourth inverter circuit can include transistors 107 and 108.

Within FIG. 1A, the sources of transistors 101, 103, 105 and 107 can each be coupled to a voltage source (Vdd) 109 having a high voltage value (e.g., logic “1”) while the sources of transistors 102, 104, 106 and 108 can each be coupled to a voltage ground 110 having a low voltage value (e.g., logic “0”). The gates of transistors 101 and 102 can be coupled to a node 111 and to the drains of transistors 105 and 106. The drains of transistors 101 and 102 can be coupled to the gates of transistors 103 and 104. The drains of transistors 103 and 104 can be coupled to a node 112 and to the gates of transistors 107 and 108. The drains of transistors 107 and 108 can be coupled to the gates of transistors 105 and 106.

Note that each of transistors 101-108 can be implemented in a wide variety of ways in accordance with embodiments of the invention. For example, each of transistors 101-108 can be implemented as, but is not limited to, a P-channel MOSFET (metal-oxide semiconductor field-effect transistor) which is also known as a PMOS or PFET. Furthermore, each of transistors 101-108 can be implemented as, but is not limited to, a N-channel MOSFET which is also known as a NMOS or NFET. It is appreciated that each of transistors 101-108 can be implemented as, but is not limited to, a PFET, a NFET, or any other type of transistor. Note that each of transistors 101-108 can be referred to as a switching element. It is appreciated that a gate, a drain, and a source of a transistor can each be referred to as a terminal of its transistor. Additionally, the gate of a transistor can also be referred to as a control terminal of its transistor.

It is appreciated that storage element circuit 100 may not include all of the elements illustrated by FIG. 1A. Furthermore, storage element circuit 100 can be implemented to include other elements not shown by FIG. 1A.

FIG. 1B is a schematic of an exemplary static look aside non-inverting keeper storage element circuit 113 in accordance with embodiments of the invention. Storage element circuit 113 includes a positive feedback loop with four inverter circuits coupled in sequential series. Specifically, the output of inverter circuit 114 can be coupled to the input of inverter circuit 115. The output of inverter circuit 115 can be coupled to the input of inverter circuit 116. The output of inverter circuit 116 can be coupled to the input of inverter circuit 117. Additionally, the output of inverter circuit 116 can be coupled to the input of inverter circuit 114 and to a node 118. Understand that any two of the inverter circuits 114-117 can be referred to as redundant elements of storage element circuit 113.

It is appreciated that storage element circuit 113 may not include all of the elements illustrated by FIG. 1B. Furthermore, storage element circuit 113 can be implemented to include other elements not shown by FIG. 1B. For example, in one embodiment, any even number of inverter circuits (e.g., 115) can be included as part of keeper storage element circuit 113. It is noted that each of the inverter circuits 114-117 can be implemented in a similar manner to any inverter circuit described herein, but is not limited to such.

FIG. 1C is a schematic of an exemplary static inverting buffered asymmetric storage element circuit 119 in accordance with embodiments of the invention. Storage element circuit 119 includes a positive feedback loop with four inverter circuits coupled in sequential series. Specifically, the output of inverter circuit 120 can be coupled to a node 125 and to the input of inverter circuit 121. The output of inverter circuit 121 can be coupled to the input of inverter circuit 122. The output of inverter circuit 122 can be coupled to the input of inverter circuit 123. Furthermore, the output of inverter circuit 123 can be coupled to a node 124 and to the input of inverter circuit 120. Understand that any two of the inverter circuits 121-123 can be referred to as redundant elements of storage element circuit 113.

It is appreciated that storage element circuit 119 may not include all of the elements illustrated by FIG. 1C. Furthermore, storage element circuit 119 can be implemented to include other elements not shown by FIG. 1C. For example, in one embodiment, any even number of inverter circuits can be coupled in series with inverters 121-123 between node 125 and node 124. Alternatively, in another embodiment, any odd number of inverter circuits can be coupled in series with inverter 120 between node 124 and node 125. It is noted that each of the inverter circuits 120-124 can be implemented in a similar manner to any inverter circuit described herein, but is not limited to such.

FIG. 1D is a schematic of an exemplary static inverting buffered asymmetric storage element circuit 126 in accordance with embodiments of the invention. Storage element circuit 126 includes two logic NAND gate circuits along with two inverter circuits coupled in series. Specifically, the output of NAND gate circuit 127 can be coupled to a node 133 and to the input of inverter circuit 129. The output of inverter circuit 129 can be coupled to the input of inverter circuit 130. The output of inverter circuit 130 can be coupled to a first input of NAND gate circuit 128. A second input of NAND gate 128 can be coupled to a node 132. The output of NAND gate 128 can be coupled to a first input of NAND gate 127. A second input of NAND gate 127 can be coupled to a node 131. Understand that inverter circuits 129 and 130 can be referred to as redundant elements of storage element circuit 126.

It is appreciated that storage element circuit 126 may not include all of the elements illustrated by FIG. 1D. Moreover, storage element circuit 126 can be implemented to include other elements not shown by FIG. 1D. For example, in one embodiment, any even number of inverter circuits can be coupled in series with inverters 129 and 130. Alternatively, in another embodiment, any even number of inverter circuits can be coupled in series between the output of NAND gate 128 and the first input of NAND gate 127. It is appreciated that each of the inverter circuits 129 and 130 can be implemented in a similar manner to any inverter circuit described herein, but is not limited to such. Furthermore, each of the NAND gates 127 and 128 can be implemented in a similar manner to any NAND gate circuit described herein, but is not limited to such.

FIG. 1E is a schematic of an exemplary static buffered asymmetric storage element circuit 134 in accordance with embodiments of the invention. Storage element circuit 134 includes two logic NAND gate circuits 135 and 136 coupled together. Specifically, the output of NAND gate circuit 135 can be coupled to a node 139 and to both a first input and a second input of NAND gate circuit 136. A third input of NAND gate 136 can be coupled to a node 138. The output of NAND gate 136 can be coupled to a node 140 and to a first input of NAND gate 135. A second input of NAND gate 135 can be coupled to a node 137. Understand that the first input or the second input (along with its accompanying circuitry that is not shown) of NAND gate 136 can be referred to as redundant elements of storage element circuit 134.

It is appreciated that storage element circuit 134 may not include all of the elements illustrated by FIG. 1E. Additionally, storage element circuit 134 can be implemented to include other elements not shown by FIG. 1E. For example, in one embodiment, an additional one or more inputs along with their accompanying circuitry can be implemented as part of NAND gate 135. Understand that each of the NAND gates 135 and 136 can be implemented in a similar manner to any NAND gate circuit described herein, but is not limited to such.

FIG. 1F is a schematic of an exemplary static buffered asymmetric storage element circuit 141 in accordance with embodiments of the invention. Storage element circuit 134 includes two logic NAND gate circuits 142 and 143 coupled together. Specifically, the output of NAND gate circuit 142 can be coupled to a node 147, an output of inverter circuit 144, and to a first input of NAND gate circuit 143. A second input of NAND gate 143 can be coupled to a node 146. The output of NAND gate 143 can be coupled to a node 148, an input of inverter circuit 144, and to a first input of NAND gate 142. A second input of NAND gate 142 can be coupled to a node 145. Understand that inverter circuit 144 can be referred to as a redundant element of storage element circuit 141.

It is appreciated that storage element circuit 141 may not include all of the elements illustrated by FIG. 1F. Additionally, storage element circuit 141 can be implemented to include other elements not shown by FIG. 1F. For example, in one embodiment, two additional inverter circuits can be coupled in series with inverter 144 between nodes 147 and 148. Note that any odd number of inverter circuits can be coupled in series between nodes 147 and 148. Understand that each of the NAND gates 142 and 143 can be implemented in a similar manner to any NAND gate circuit described herein, but is not limited to such.

FIG. 1G is a schematic of an exemplary static buffered symmetric storage element circuit 149 in accordance with embodiments of the invention. Storage element circuit 149 includes two logic NAND gate circuits 142 and 143 coupled together. Specifically, the output of NAND gate circuit 142 can be coupled to node 147, the output of inverter circuit 144, an input of inverter circuit 150, and to the first input of NAND gate circuit 143. The second input of NAND gate 143 can be coupled to node 146. The output of NAND gate 143 can be coupled to node 148, the input of inverter circuit 144, an output of inverter circuit 150, and to the first input of NAND gate 142. The second input of NAND gate 142 can be coupled to node 145. Appreciate that inverter circuits 144 and 150 can be referred to as redundant elements of storage element circuit 149.

It is understood that storage element circuit 149 may not include all of the elements illustrated by FIG. 1G. Furthermore, storage element circuit 149 can be implemented to include other elements not shown by FIG. 1G. For example, in one embodiment, any even number of inverter circuits can be coupled in series with inverter 144 between nodes 147 and 148. Moreover, any even number of inverter circuits can be coupled in series with inverter 150 between nodes 147 and 148. Understand that each of the NAND gates 142 and 143 can be implemented in a similar manner to any NAND gate circuit described herein, but is not limited to such.

FIG. 1H is a schematic of an exemplary static buffered symmetric storage element circuit 151 in accordance with embodiments of the invention. Storage element circuit 151 includes two storage element circuits coupled together. Specifically, a first storage element circuit includes logic NAND gate circuits 152 and 153 while a second (or redundant) element circuit includes logic NAND gate circuits 154 and 155. Specifically, an output of NAND gate circuit 152 can be coupled to node 158 and to a first input of NAND gate circuit 153 and to an output of NAND gate 155 and to a first input of NAND gate 154. A second input of NAND gate 153 can be coupled to node 157 and to a second input of NAND gate circuit 154. An output of NAND gate 153 can be coupled to node 159 and to a first input of NAND gate 152 and to an output of NAND gate 154 and to a first input of NAND gate 155. A second input of NAND gate 152 can be coupled to node 156 and to a second input of NAND gate circuit 155. Understand that the circuitry including NAND gates 154 and 155 can be referred to as redundant elements of storage element circuit 151.

It is appreciated that storage element circuit 151 may not include all of the elements illustrated by FIG. 1H. Moreover, storage element circuit 151 can be implemented to include other elements not shown by FIG. 1H. For example, in one embodiment, additional circuitry can be included as part of storage element circuit 151 that is similar to the circuitry including NAND gates 154 and 155. Understand that each of the NAND gates 152, 153, 154 and 155 can be implemented in a similar manner to any NAND gate circuit described herein, but is not limited to such.

FIG. 1I is a schematic of an exemplary logic NAND gate circuit 162 in accordance with embodiments of the invention. NAND gate circuit 162 can include six transistors wherein three transistors are coupled in series and three are coupled in parallel. Specifically, the gates of transistors 163 and 164 can be coupled to a node 169. The drains of transistors 163 and 164 can be coupled to the drains of transistors 167 and 168 and to a node 171. The sources of transistors 163, 167 and 168 can each be coupled to a voltage source (Vdd) 172 having a high voltage value (e.g., logic “1”). The gates of transistor 165-168 can be coupled to a node 170. The source of transistor 164 can be coupled to the drain of transistor 165 while the source of transistor 165 can be coupled to the drain of transistor 166. The source of transistor 166 can be coupled to a voltage ground 173 having a low voltage value (e.g., logic “0”). Understand that transistors 165 and 167 can each be referred to as a redundant element of NAND gate circuit 162.

It is appreciated that NAND gate 162 may not include all of the elements illustrated by FIG. 1I. Additionally, NAND gate 162 can be implemented to include other elements not shown by FIG. 1I.

FIG. 1J is a schematic of an exemplary logic NAND gate circuit 174 in accordance with embodiments of the invention. NAND gate circuit 174 can include six transistors wherein some transistors are coupled in series and some are coupled in parallel. Specifically, the gates of transistors 175, 176 and 179 can be coupled to a node 181. The drains of transistors 175, 176 and 179 can be coupled to the drain of transistor 178 and to a node 183. The sources of transistors 175 and 178 can each be coupled to a voltage source (Vdd) 184 having a high voltage value (e.g., logic “1”). The gates of transistors 177, 180 and 178 can be coupled to a node 182. The sources of transistors 177 and 180 can be coupled to a voltage ground 185 having a low voltage value (e.g., logic “0”). The drain of transistor 177 can be coupled to the source of transistor 176 while the drain of transistor 180 can be coupled to the source of transistor 179. Understand that transistors 180 and 179 can each be referred to as a redundant element of NAND gate circuit 174. Also, transistors 180 and 179 together can be referred to as a redundant element of NAND gate circuit 174.

It is noted that NAND gate 174 may not include all of the elements illustrated by FIG. 1J. Additionally, NAND gate 174 can be implemented to include other elements not shown by FIG. 1J.

FIG. 1K is a schematic of an exemplary logic NAND gate circuit 186 in accordance with embodiments of the invention. NAND gate circuit 186 can include six transistors wherein four transistors are coupled in series and the other two are coupled in series. Specifically, the gates of transistors 187, 188 and 189 can be coupled to a node 193. The gates of transistors 190, 191 and 192 can be coupled to a node 194. The sources of transistors 187 and 191 can each be coupled to a voltage source (Vdd) 196 having a high voltage value (e.g., logic “1”). The drain of transistor 187 can be coupled to the source of transistor 188 while the drain of transistor 191 can be coupled to the source of transistor 192. The drains of 188, 189 and 192 can be coupled to a node 195. The source of transistor 189 can be coupled to the drain of transistor 190 while the source of transistor 190 can be coupled to a voltage ground 197 having a low voltage value (e.g., logic “0”). Understand that transistors 188 and 192 can each be referred to as a redundant element of NAND gate circuit 186.

It is appreciated that NAND gate 186 may not include all of the elements illustrated by FIG. 1K. Additionally, NAND gate 186 can be implemented to include other elements not shown by FIG. 1K.

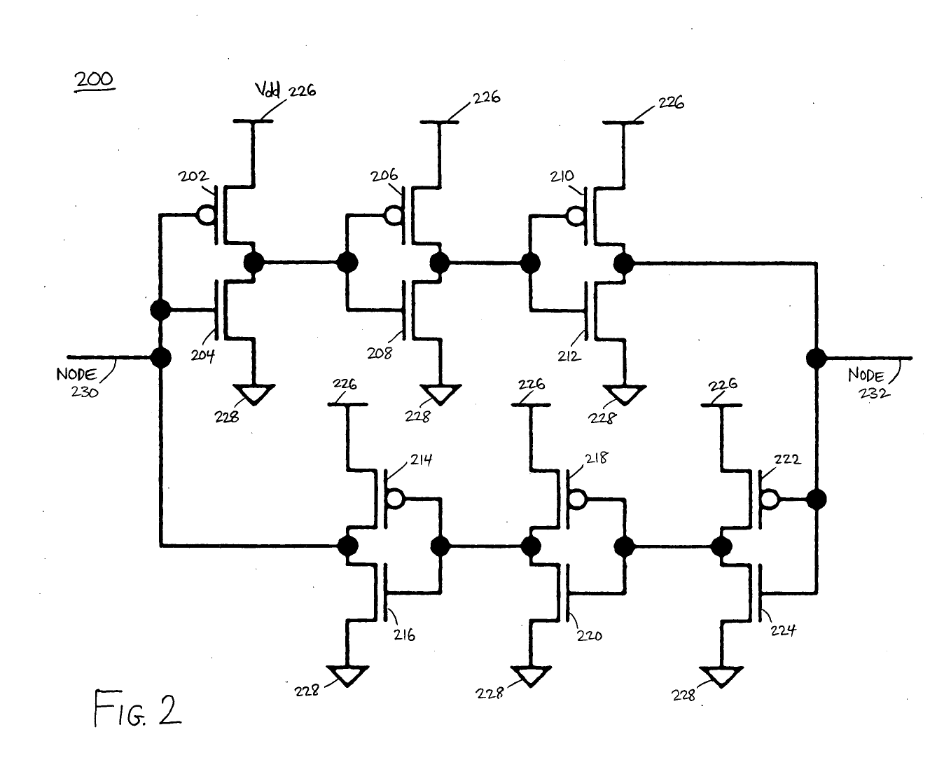

FIG. 2 is a schematic of an exemplary series hex inverter static storage element circuit 200 in accordance with embodiments of the invention. Storage element circuit 200 includes six inverter circuits coupled in a sequential series chain. Specifically, a first inverter circuit of storage element circuit 200 can include transistors 202 and 204, a second inverter circuit can include transistors 206 and 208, a third inverter circuit can include transistors 210 and 212, a fourth inverter circuit can include transistors 214 and 216, a fifth inverter circuit can include transistors 218 and 220, and a sixth inverter circuit can include transistors 222 and 224.

Within FIG. 2, the sources of transistors 202, 206, 210, 214, 218 and 222 can each be coupled to a voltage source (Vdd) 226 having a high voltage value (e.g., logic “1”) while the sources of transistors 204, 208, 212, 216, 220 and 224 can each be coupled to a voltage ground 228 having a low voltage value (e.g., logic “0”). The gates of transistors 202 and 204 can be coupled to a node 230 and to the drains of transistors 214 and 216. The drains of transistors 202 and 204 can be coupled to the gates of transistors 206 and 208. The drains of transistors 206 and 208 can be coupled to the gates of transistors 210 and 212. The drains of transistors 210 and 212 can be coupled to a node 232 and to the gates of transistors 222 and 224. The drains of transistors 222 and 224 can be coupled to the gates of transistors 218 and 220. The drains of transistors 218 and 220 can be coupled to the gates of transistors 214 and 216.

Note that each of transistors 202-224 can be implemented in a wide variety of ways in accordance with embodiments of the invention. For example, each of transistors 202-224 can be implemented as, but is not limited to, a PFET, a NFET, or any other type of transistor. It is understood that each of transistors 202-224 can be referred to as a switching element.

It is appreciated that storage element circuit 200 may not include all of the elements illustrated by FIG. 2. Furthermore, storage element circuit 200 can be implemented to include other elements not shown by FIG. 2. For example, any additional even number of inverters can be added to storage element circuit 200.

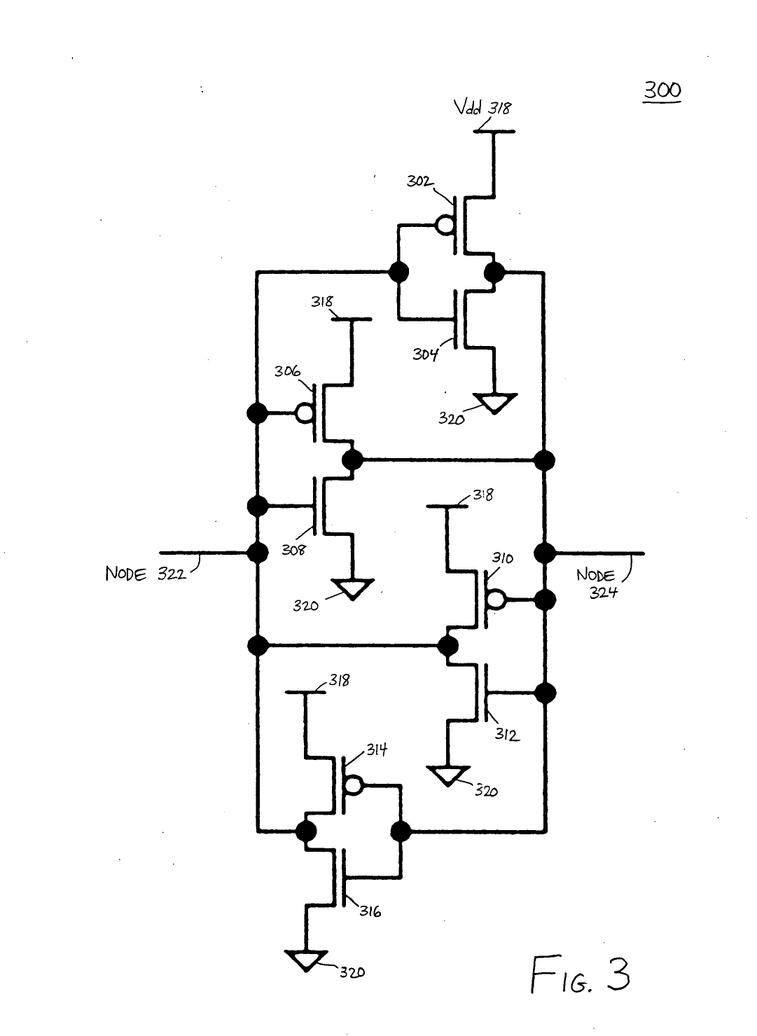

FIG. 3 is a schematic of an exemplary parallel quad inverter static storage element circuit 300 in accordance with embodiments of the invention. Storage element circuit 300 includes four inverters coupled in parallel forming a loop that is two inverters deep and two inverters wide.

Storage element circuit 300 includes four inverter circuits coupled in parallel forming a loop. Specifically, a first inverter circuit of storage element circuit 300 can include transistors 302 and 304, a second inverter circuit can include transistors 306 and 308, a third inverter circuit can include transistors 310 and 312, and a fourth inverter circuit can include transistors 314 and 316.

Within FIG. 3, the sources of transistors 302, 306, 310 and 314 can each be coupled to a voltage source (Vdd) 318 having a high voltage value (e.g., logic “1”) while the sources of transistors 304, 308, 312 and 316 can each be coupled to a voltage ground 320 having a low voltage value (e.g., logic “0”). The gates of transistors 302, 304, 306 and 308 can be coupled to a node 322 and to the drains of transistors 310, 312, 314 and 316. The drains of transistors 302, 304, 306 and 308 can be coupled to a node 324 and to the gates of transistors 310, 312, 314 and 316.

Note that each of transistors 302-316 can be implemented in a wide variety of ways in accordance with embodiments of the invention. For example, each of transistors 302-316 can be implemented as, but is not limited to, a PFET, a NFET, or any other type of transistor. It is appreciated that each of transistors 302-316 can be referred to as a switching element.

It is appreciated that storage element circuit 300 may not include all of the elements illustrated by FIG. 3. For example, in one embodiment, the redundant inverter circuit that includes transistors 310 and 312 can be removed from circuit 300 causing it to become an exemplary asymmetric parallel tri inverter static storage element circuit. In another embodiment, the redundant inverter circuit that includes transistors 302 and 304 can be removed from circuit 300 which also causes it to become an exemplary asymmetric parallel tri inverter static storage element circuit. Furthermore, storage element circuit 300 can be implemented to include other elements not shown by FIG. 3.

FIG. 4 is a schematic of an exemplary parallel hex inverter static storage element circuit 400 in accordance with embodiments of the invention. Storage element circuit 400 includes six inverters coupled in parallel forming a loop that is two inverters deep and three inverters wide.

Storage element circuit 400 includes six inverter circuits coupled in parallel forming a loop. Specifically, a first inverter circuit of storage element circuit 400 can include transistors 402 and 404, a second inverter circuit can include transistors 406 and 408, a third inverter circuit can include transistors 410 and 412, a fourth inverter circuit can include transistors 414 and 416, a fifth inverter circuit can include transistors 418 and 420, and a sixth inverter circuit can include transistors 422 and 424.

Within FIG. 4, the sources of transistors 402, 406, 410, 414, 418 and 422 can each be coupled to a voltage source (Vdd) 426 having a high voltage value (e.g., logic “1”) while the sources of transistors 404, 408, 412, 416, 420 and 424 can each be coupled to a voltage ground 428 having a low voltage value (e.g., logic “0”). The gates of transistors 402, 404, 406, 408, 410 and 412 can be coupled to a node 430 and to the drains of transistors 414, 416, 418, 420, 422 and 424. The drains of transistors 402, 404, 406, 408, 410 and 412 can be coupled to a node 432 and to the gates of transistors 414, 416, 418, 420, 422 and 424.

Note that each of transistors 402-424 can be implemented in a wide variety of ways in accordance with embodiments of the invention. For example, each of transistors 402-424 can be implemented as, but is not limited to, a PFET, a NFET, or any other type of transistor. It is understood that each of transistors 402-424 can be referred to as a switching element.

It is appreciated that storage element circuit 400 may not include all of the elements illustrated by FIG. 4. Furthermore, storage element circuit 400 can be implemented to include other elements not shown by FIG. 4. For example, any additional odd or even number of inverters can be added to storage element circuit 400 such that it can be four inverters wide, five inverters wide, and so forth.

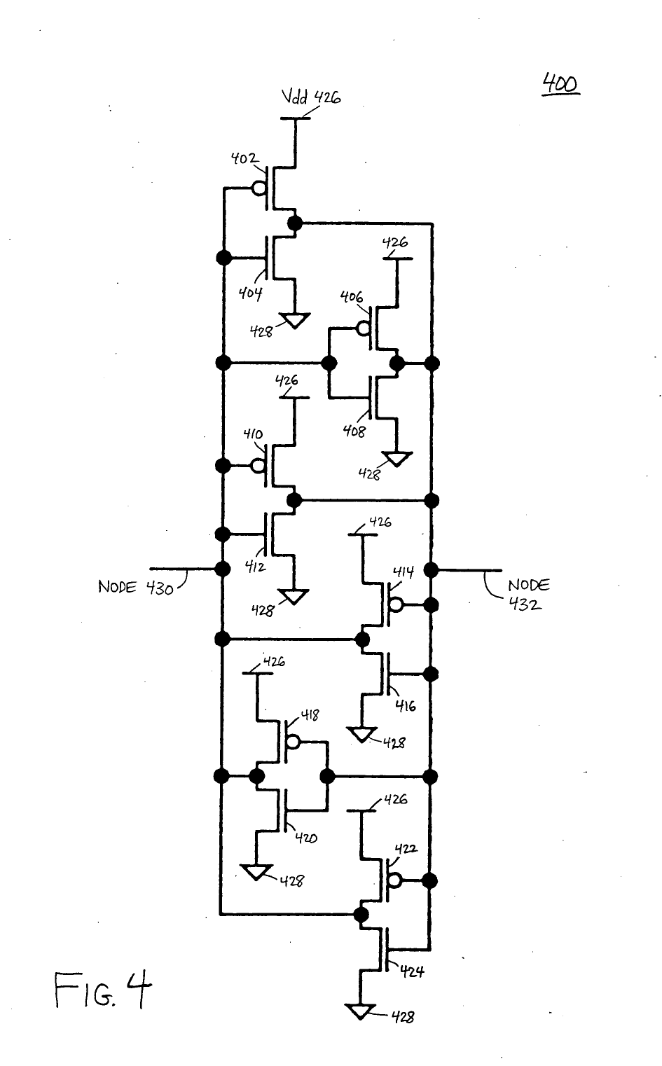

FIG. 5 is a schematic of an exemplary stacked inverter static storage element circuit 500 in accordance with embodiments of the invention. Storage element circuit 500 includes two double stacked inverter stages, wherein each inverter stage includes four transistors.

Storage element circuit 500 includes two inverter circuits. Specifically, a first inverter circuit of storage element circuit 500 can include transistors 502, 504, 506 and 508 while a second inverter circuit can include transistors 510, 512, 514 and 516.

Within FIG. 5, the sources of transistors 502 and 510 can each be coupled to a voltage source (Vdd) 518 having a high voltage value (e.g., logic “1”) while the sources of transistors 508 and 516 can each be coupled to a voltage ground 520 having a low voltage value (e.g., logic “0”). The gates of transistors 502, 504, 506 and 508 can be coupled to a node 522 and to the drains of transistors 512 and 514. The gates of transistors 510, 512, 514 and 516 can be coupled to a node 524 and to the drains of transistors 504 and 506. The drain of transistor 502 can be coupled to the source of transistor 504. The source of transistor 506 can be coupled to the drain of transistor 508. Additionally, the drain of transistor 510 can be coupled to the source of transistor 512. The source of transistor 514 can be coupled to the drain of transistor 516.

Each of transistors 502-516 can be implemented in a wide variety of ways in accordance with embodiments of the invention. For example, each of transistors 502-516 can be implemented as, but is not limited to, a PFET, a NFET, or any other type of transistor. It is noted that each of transistors 502-516 can be referred to as a switching element.

It is appreciated that storage element circuit 500 may not include all of the elements illustrated by FIG. 5. Furthermore, storage element circuit 500 can be implemented to include other elements not shown by FIG. 5. For example, other permutations of stacking are possible within storage element circuit 500. For instance, one of the transistor types of storage element circuit 500 could have any number of stacks and the other transistor type could have any number of stacks (similar or different from the first). Furthermore, each inverter stage of storage element circuit 500 can be implemented with a different number of stacks.

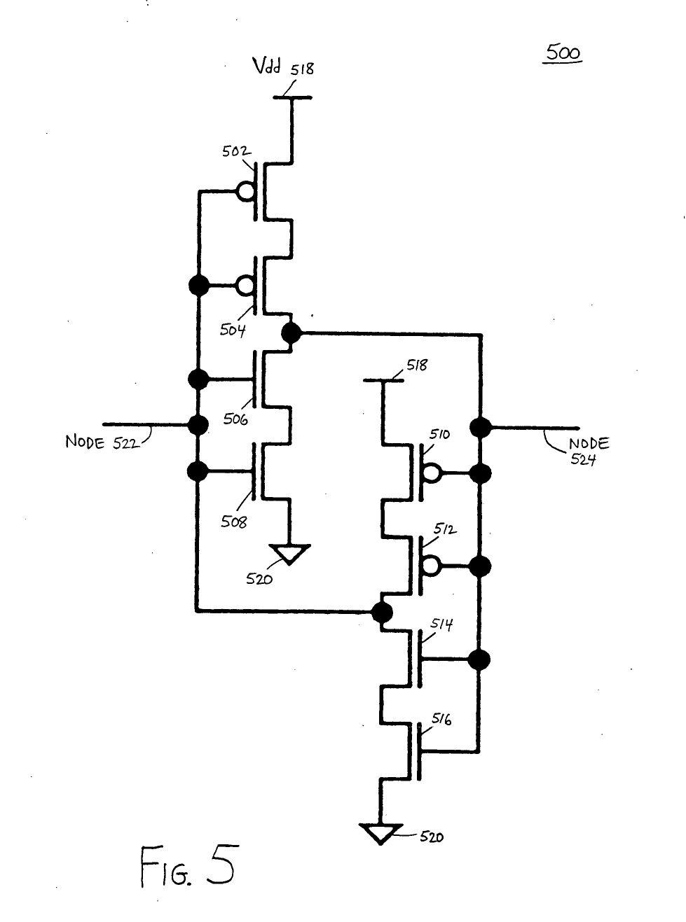

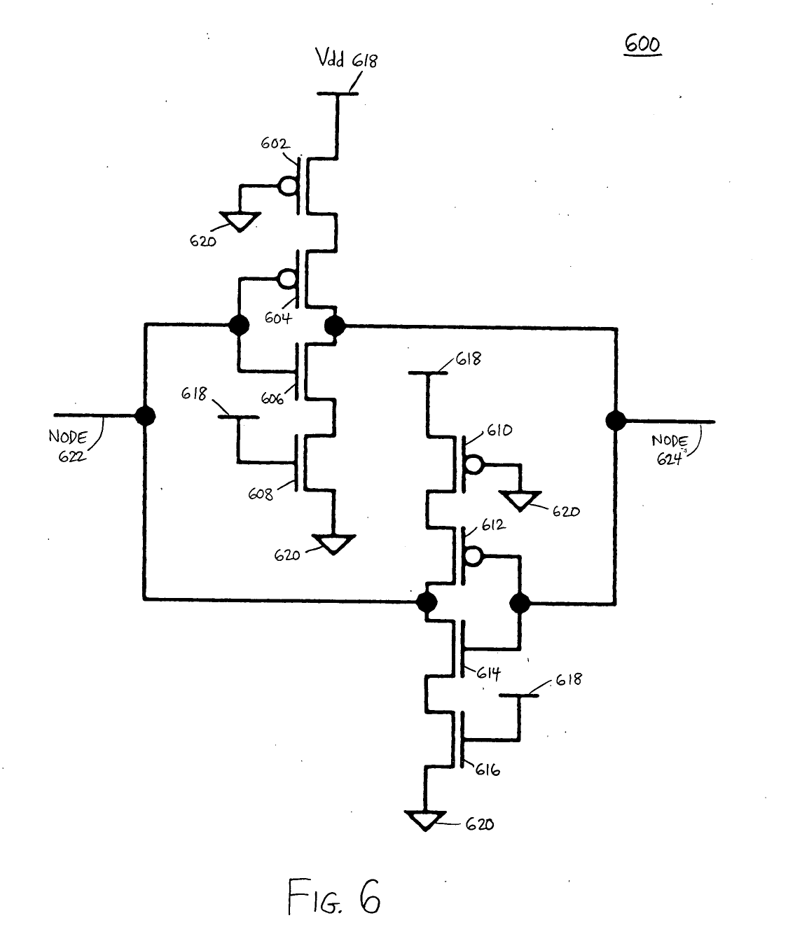

FIG. 6 is a schematic of an exemplary dummy stacked inverter static storage element circuit 600 in accordance with embodiments of the invention. Storage element circuit 600 includes two dummy stacked inverter stages, wherein each inverter stage includes four transistors.

Storage element circuit 600 includes two dummy stacked inverter stage circuits. Specifically, a first dummy stacked inverter circuit of storage element circuit 600 can include transistors 602, 604, 606 and 608. Note that “dummy” transistors 602 and 608 can be referred to as “degenerate” devices since they are “ON” devices. For example, the gate of transistor 602 can be coupled to a voltage ground 620 while the gate of transistor 608 to a voltage source (Vdd) 618 thereby causing both to remain “ON” or in a conducting state. A second inverter circuit of storage element circuit 600 can include transistors 610, 612, 614 and 616, wherein “dummy” transistors 610 and 616 can be referred to “degenerate” devices. It is noted that “dummy” transistors 602, 608, 610 and 616 are not coupled to a driving signal of storage element 600.

Within FIG. 6, the sources of transistors 602 and 610 along with the gates of transistors 608 and 616 can each be coupled to a voltage source (Vdd) 618 having a high voltage value (e.g., logic “1”). Additionally, the sources of transistors 608 and 616 along with the gates of transistors 602 and 610 can each be coupled to a voltage ground 620 having a low voltage value (e.g., logic “0”). The gates of transistors 604 and 606 can be coupled to a node 622 and to the drains of transistors 612 and 614. The gates of transistors 612 and 614 can be coupled to a node 624 and to the drains of transistors 604 and 606. The drain of transistor 602 can be coupled to the source of transistor 604. The source of transistor 606 can be coupled to the drain of transistor 608. Furthermore, the drain of transistor 610 can be coupled to the source of transistor 612. The source of transistor 614 can be coupled to the drain of transistor 616.

Each of transistors 602-616 can be implemented in a wide variety of ways in accordance with embodiments of the invention. For example, each of transistors 602-616 can be implemented as, but is not limited to, a PFET, a NFET, or any other type of transistor. It is appreciated that each of transistors 602-616 can be referred to as a switching element.

It is appreciated that storage element circuit 600 may not include all of the elements illustrated by FIG. 6. Furthermore, storage element circuit 600 can be implemented to include other elements not shown by FIG. 6. For example, each inverter stage of storage element circuit 600 can be implemented with additional driven transistors in a manner similar to storage element 500 of FIG. 5.

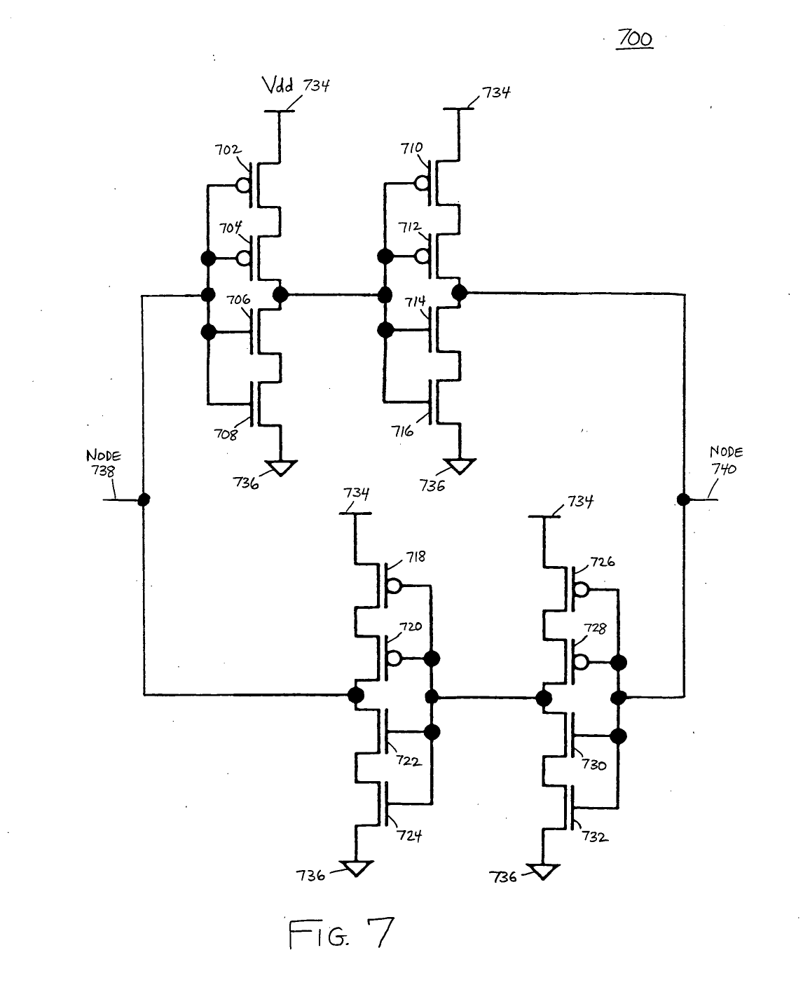

FIG. 7 is a schematic of an exemplary series quad double stack inverter static storage element circuit 700 in accordance with embodiments of the invention. Storage element circuit 700 includes four double stacked inverter stages coupled in series, wherein each inverter stage includes four transistors.

Storage element circuit 500 includes four inverter circuits. Specifically, a first inverter circuit of storage element circuit 700 can include transistors 702, 704, 706 and 708, a second inverter circuit can include transistors 710, 712, 714 and 716, a third inverter circuit can include transistors 718, 720, 722 and 724, a fourth inverter circuit can include transistors 726, 728, 730 and 732.

Within FIG. 7, the sources of transistors 702, 710, 718 and 726 can each be coupled to a voltage source (Vdd) 734 having a high voltage value (e.g., logic “1”) while the sources of transistors 708, 716, 724 and 732 can each be coupled to a voltage ground 736 having a low voltage value (e.g., logic “0”). The gates of transistors 702, 704, 706 and 708 can be coupled to node 738 and to the drains of transistors 720 and 722. Moreover, the gates of transistors 718, 720, 722 and 724 can be coupled to the drains of transistors 728 and 730. The gates of transistors 726, 728, 730 and 732 can be coupled to node 740 and to the drains of transistors 712 and 714. Additionally, the gates of transistors 710, 712, 714 and 716 can be coupled to the drains of transistors 704 and 706. The drain of transistor 702 can be coupled to the source of transistor 704. The source of transistor 706 can be coupled to the drain of transistor 708. Furthermore, the drain of transistor 710 can be coupled to the source of transistor 712. The source of transistor 714 can be coupled to the drain of transistor 716. The drain of transistor 718 can be coupled to the source of transistor 720. The source of transistor 722 can be coupled to the drain of transistor 724. Also, the drain of transistor 726 can be coupled to the source of transistor 728. The source of transistor 730 can be coupled to the drain of transistor 732.

Note that each of transistors 702-732 can be implemented in a wide variety of ways in accordance with embodiments of the invention. For example, each of transistors 702-732 can be implemented as, but is not limited to, a PFET, a NFET, or any other type of transistor. It is appreciated that each of transistors 702-732 can be referred to as a switching element.

It is appreciated that storage element circuit 700 may not include all of the elements illustrated by FIG. 7. Furthermore, storage element circuit 700 can be implemented to include other elements not shown by FIG. 7.

Note that storage element circuit embodiments in accordance with the invention can be formed or generated using any combination of storage element circuits 100, 113, 119, 126, 134, 141, 149, 151, 162, 174, 186, 200, 300, 400, 500, 600 and/or 700. Furthermore, storage element circuit embodiments in accordance with the invention can be formed or generated by using any component combinations from storage element circuits 100, 113, 119, 126, 134, 141, 149, 151, 162, 174, 186, 200, 300, 400, 500, 600 and/or 700. Moreover, storage element circuit embodiments in accordance with the invention can be formed or generated using any combination of redundancy replacement rules 900, 910, 920, 930, 940, 950, 1000, 1010, 1020, 1030, 1040, 1050 and/or 1060. It is understood that storage element circuit embodiments in accordance with the invention can be formed or generated using any combination of the embodiments described herein, but is not limited to such.

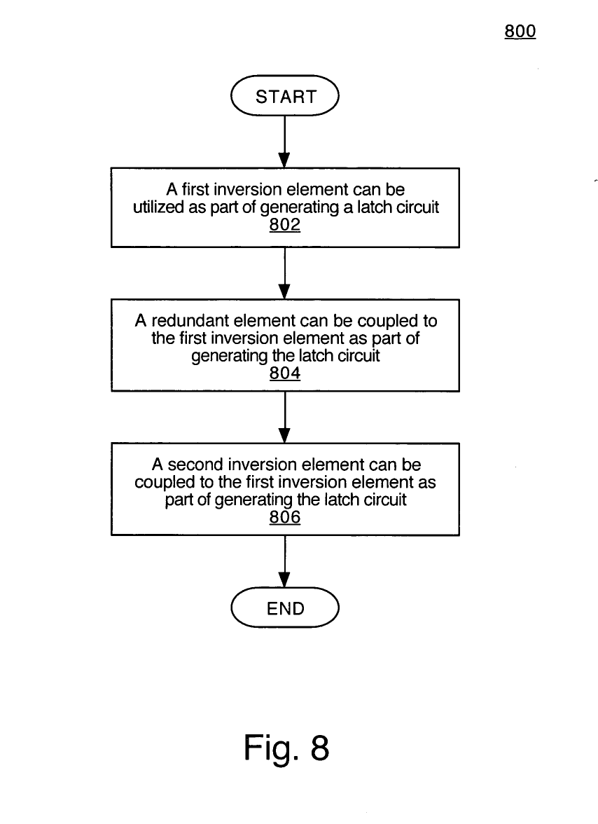

FIG. 8 is a flowchart of a method 800 in accordance with embodiments of the invention for generating a storage element circuit. Method 800 includes exemplary processes of embodiments of the invention which can be carried out by a processor(s) and electrical components under the control of computing device readable and executable instructions (or code), e.g., software. The computing device readable and executable instructions (or code) may reside, for example, in data storage features such as volatile memory, non-volatile memory and/or mass data storage that are usable by a computing device. However, the computing device readable and executable instructions (or code) may reside in any type of computing device readable medium. Although specific operations are disclosed in method 800, such operations are exemplary. That is, method 800 may not include all of the operations illustrated by FIG. 8. Alternatively, method 800 may include various other operations and/or variations of the operations shown by FIG. 8. Likewise, the sequence of the operations of method 800 can be modified. It is noted that the operations of method 800 can each be performed by software, by firmware, by electronic hardware, or by any combination thereof.

Specifically, a first inversion element can be utilized as part of generating a storage element circuit. Additionally, a redundant element can be coupled to the first inversion element as part of generating the storage element circuit. A second inversion element can also be coupled to the first inversion element as part of generating the storage element circuit. Note that the storage element circuit of method 800 can be implemented in any manner similar to the storage element circuits described herein, but is not limited to such.

At operation 802 of FIG. 8, a first inversion element can be utilized as part of generating a storage element circuit. It is understood that operation 802 can be implemented in a wide variety of ways. For example, the first inversion element can be implemented in any manner similar to the one or more inverters described herein, but is not limited to such.

At operation 804, a redundant element can be coupled to the first inversion element as part of generating the storage element circuit. It is appreciated that operation 804 can be implemented in a wide variety of ways. For example, the redundant element can be implemented as, but is not limited to, one or more transistors, one or more inversion elements, and one or more inverters. Furthermore, the first inversion element and the redundant element can be a stacked inverter in any manner similar to that described herein, but not limited to such.

At operation 806 of FIG. 8, a second inversion element can also be coupled to the first inversion element as part of generating the storage element circuit. It is noted that operation 806 can be implemented in a wide variety of ways. For example, the second inversion element can be implemented in any manner similar to the one or more inverters described herein, but is not limited to such. Furthermore, the redundant element can be coupled in series to the first inversion element and the second inversion element. Alternatively, the redundant element can be coupled in parallel to the first inversion element and the second inversion element. Understand that the first and second inversion elements along with the redundant element can be coupled in any manner similar to that described herein, but is not limited to such.

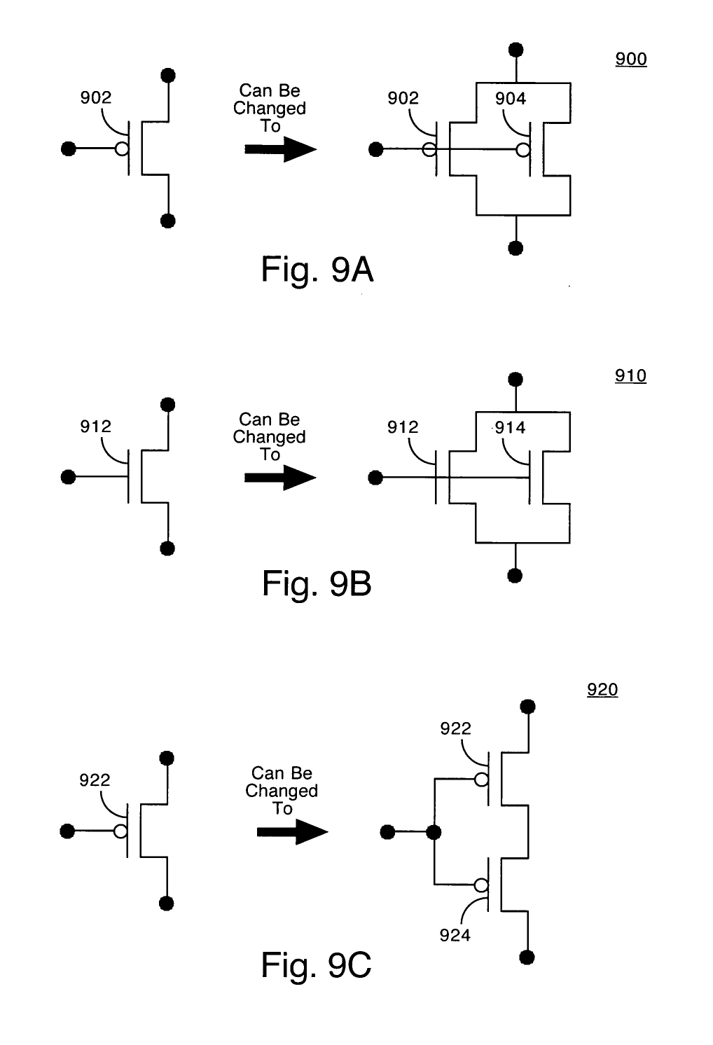

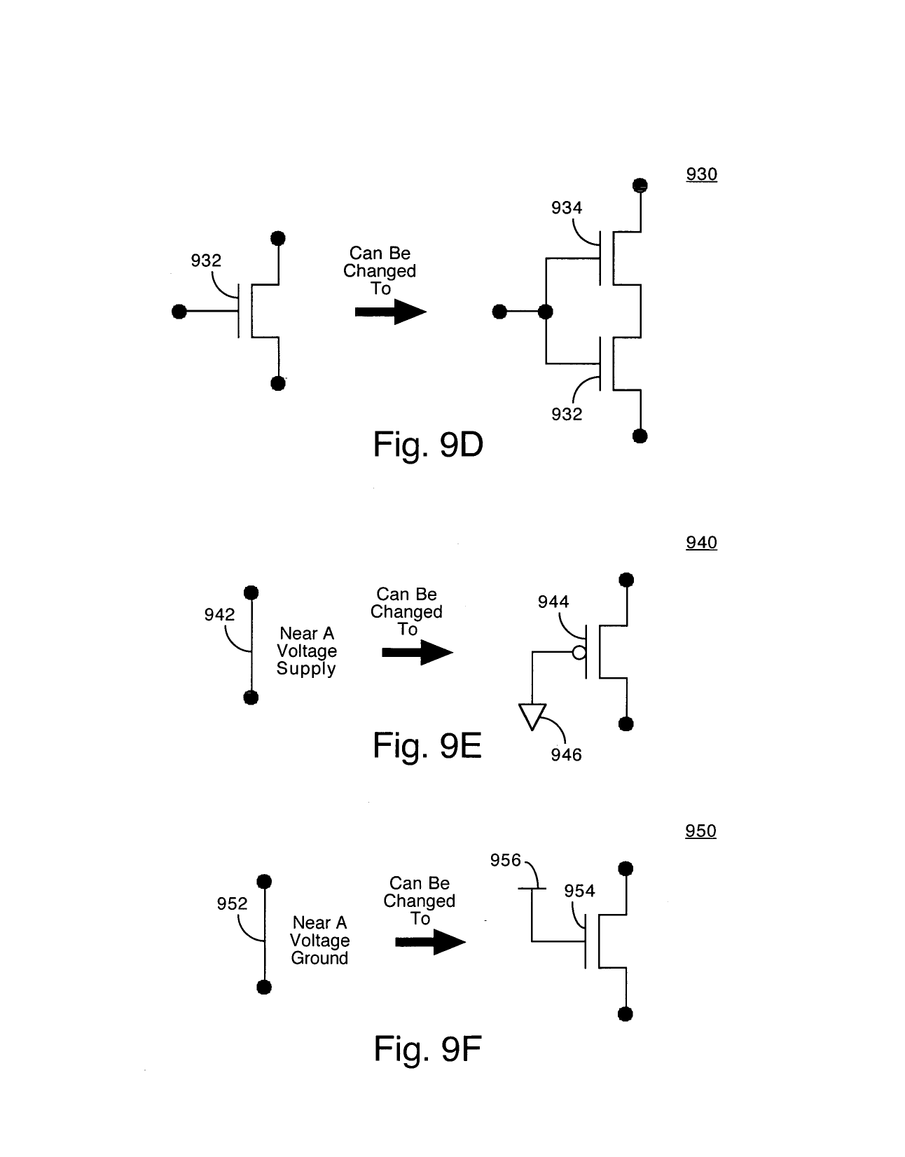

FIGS. 9A-9F illustrate different exemplary transistor redundancy replacements rules in accordance with embodiments of the invention. By starting with the given figure or situation illustrated on the left side of each of rules 900, 910, 920, 930, 940 and 950, one can map to the corresponding redundancy replacement circuit shown on the right side of rules 900, 910, 920, 930, 940 and 950. Thus, by utilizing replacement rules 900, 910, 920, 930, 940 and 950 in any combination, one can synthesize circuitry in a wide variety of ways.

FIG. 9A illustrates an exemplary parallel redundancy replacement rule 900 in accordance with embodiments of the invention. Given an exemplary PFET transistor 902 as shown on the left side of rule 900, one or more additional PFET transistors (e.g., 904) can be coupled in parallel with transistor 902 as shown on the right side of rule 900. Specifically, the gates of PFET transistors 902 and 904 are coupled together while their sources are coupled together. Additionally, the drains of PFET transistors 902 and 904 are coupled together. As such, the one or more additional PFET transistors (e.g., 904) coupled in parallel with transistor 902 can each be referred to as a redundant element.

FIG. 9B illustrates an exemplary parallel redundancy replacement rule 910 in accordance with embodiments of the invention. Given an exemplary NFET transistor 912 as shown on the left side of rule 910, one or more additional NFET transistors (e.g., 914) can be coupled in parallel with transistor 912 as shown on the right side of rule 900. Specifically, the gates of NFET transistors 912 and 914 can be coupled together while their sources are coupled together. Additionally, the drains of NFET transistors 912 and 914 can be coupled together. Therefore, the one or more additional NFET transistors (e.g., 914) coupled in parallel with transistor 912 can each be referred to as a redundant element.

FIG. 9C illustrates an exemplary series redundancy replacement rule 920 in accordance with embodiments of the invention. Given an exemplary PFET transistor 922 as shown on the left side of rule 920, one or more additional PFET transistors (e.g., 924) can be coupled in series with transistor 922 as shown on the right side of rule 920. Specifically, the gates of transistors 922 and 924 can be coupled together while the drain of transistor 922 can be coupled with the source of transistor 924. As such, the one or more additional PFET transistors (e.g., 924) coupled in series with transistor 922 can each be referred to as a redundant element.

FIG. 9D illustrates an exemplary series redundancy replacement rule 930 in accordance with embodiments of the invention. Given an exemplary NFET transistor 932 as shown on the left side of rule 930, one or more additional NFET transistors (e.g., 934) can be coupled in series with transistor 932 as shown on the right side of rule 930. Specifically, the gates of transistors 932 and 934 can be coupled together while the drain of transistor 932 can be coupled with the source of transistor 934. Therefore, the one or more additional NFET transistors (e.g., 934) coupled in series with transistor 932 can each be referred to as a redundant element.

FIG. 9E illustrates an exemplary redundancy replacement rule 940 in accordance with embodiments of the invention. Specifically, given an exemplary conductive lead 942 that is located near a voltage supply (Vdd) having a high voltage value (e.g., logic “1”) as shown on the left side of rule 940, that conductive lead 942 can be changed to or replaced by a PFET transistor 944 wherein its gate can be coupled to a voltage ground 946 having a low voltage value (e.g., logic “0”) as shown on the right side of rule 940. Therefore, that additional PFET transistor 944 coupled to ground 946 can be referred to as a redundant element.

FIG. 9F illustrates an exemplary redundancy replacement rule 950 in accordance with embodiments of the invention. Specifically, given an exemplary conductive lead 952 that is located near a voltage ground having a low voltage value (e.g., logic “0”) as shown on the left side of rule 950, that conductive lead 952 can be changed to or replaced by a NFET transistor 954 wherein its gate can be coupled to a voltage supply (Vdd) 956 having a having a high voltage value (e.g., logic “1”) as shown on the right side of rule 950. Therefore, that additional NFET transistor 954 coupled to Vdd 956 can be referred to as a redundant element.

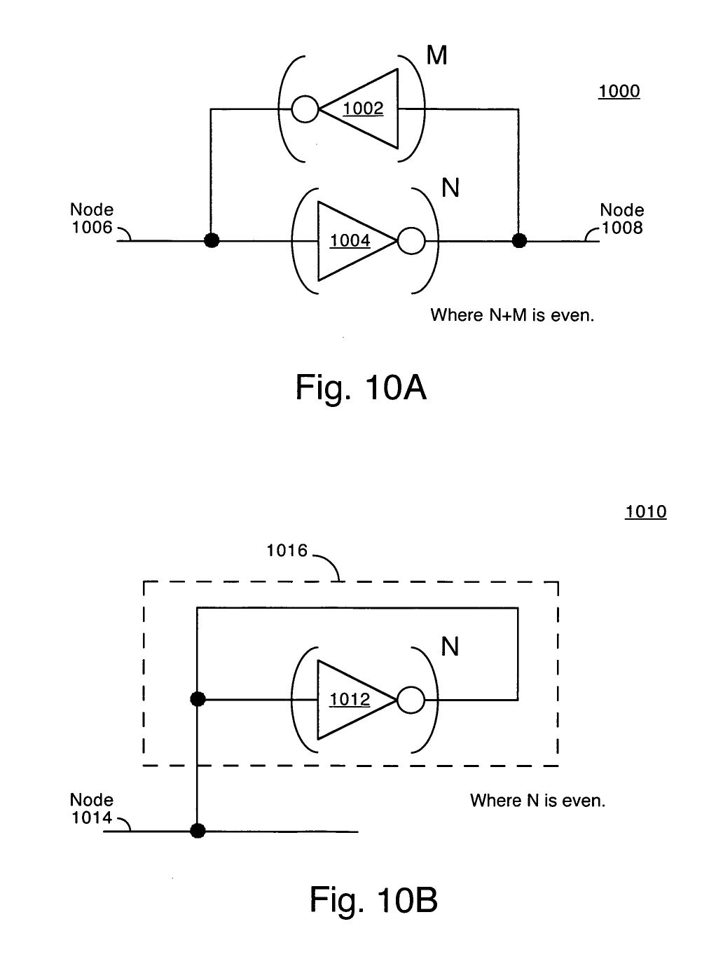

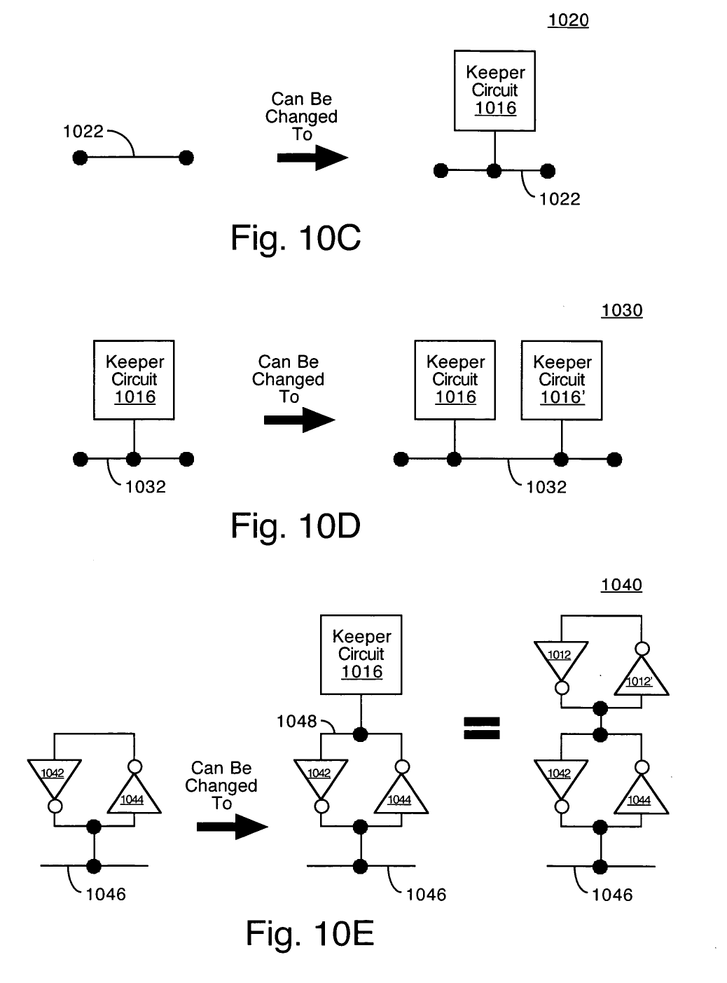

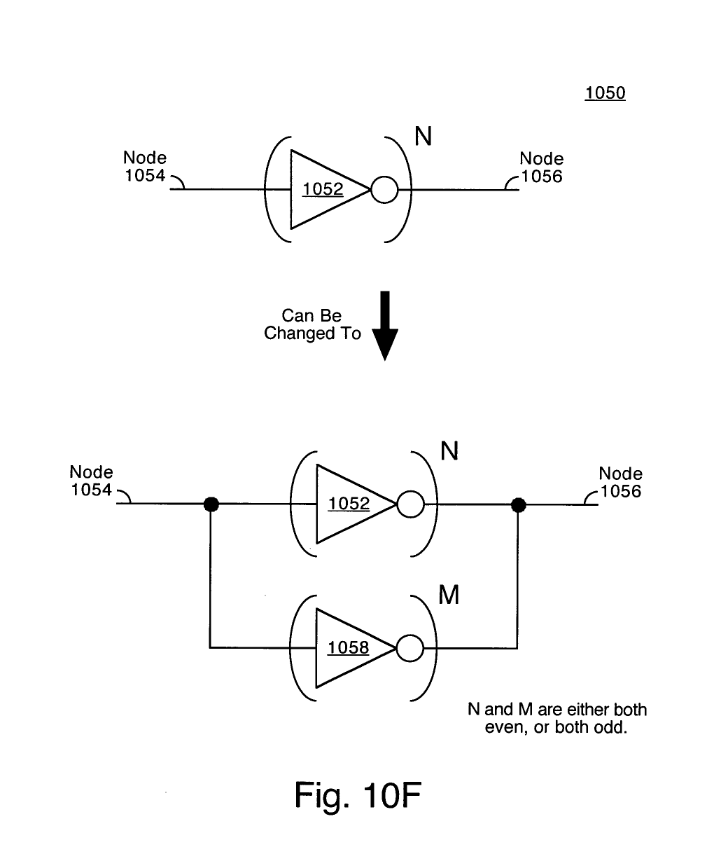

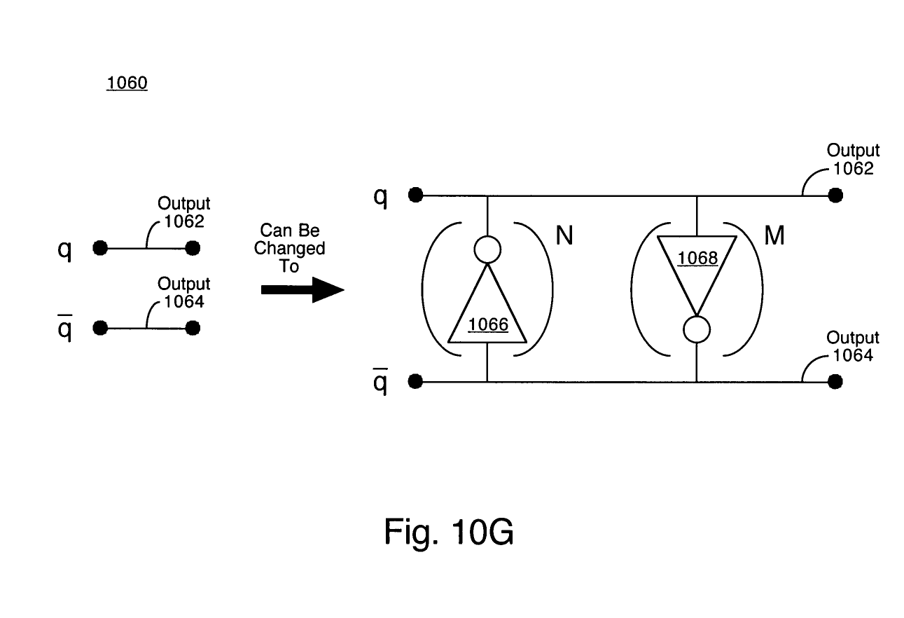

FIGS. 10A-10G illustrate different exemplary gate redundancy replacements rules in accordance with embodiments of the invention. Thus, by utilizing replacement rules 1000, 1010, 1020, 1030, 1040, 1050 and 1060 in any combination, one can synthesize circuitry in a wide variety of ways.

FIG. 10A illustrates an exemplary inverting gate redundancy replacement rule 1000 in accordance with embodiments of the invention. Note that rule 1000 can be utilized in combination with a latch circuit. The redundancy replacement rule 1000 pertains to a positive feedback loop having N+M (e.g., greater than or equal to four) inverter circuits coupled in series, wherein the number N+M of inverter circuits can be even. Specifically, a number N of one or more inverter circuits (e.g., 1004) can be coupled in series between nodes 1006 and 1008. Furthermore, a number M of one or more inverter circuits (e.g., 1002) can be coupled in series between nodes 1008 and 1006. Therefore, rule 1000 establishes that any number of redundant elements (e.g., inverter circuits) can be added to the N segment and/or the M segment of its circuit, as long as N+M is an even value, such as four, six, eight, etc.

FIG. 10B illustrates an exemplary static look aside non-inverting keeper storage element gate redundancy replacement rule 1010 in accordance with embodiments of the invention. The redundancy replacement rule 1010 pertains to a positive feedback loop keeper circuit 1016 having an even number N (e.g., greater than or equal to four) of inverter circuits coupled in sequential series. Therefore, rule 1010 establishes that any number of redundant elements (e.g., inverter circuits) can be added to the N segment of circuit 1016, as long as N is an even value, such as four, six, eight, etc.

FIG. 10C illustrates an exemplary gate redundancy replacement rule 1020 in accordance with embodiments of the invention. Specifically, given an exemplary conductive lead 1022 as shown on the left side of rule 1020, one or more keeper circuits (e.g., 1016) can be coupled to that conductive lead 1020 as shown on the right side of rule 1020. Therefore, the one or more keeper circuits (e.g., 1016) coupled to that conductive lead 1020 can each be referred to as a redundant element.

FIG. 10D illustrates an exemplary gate redundancy replacement rule 1030 in accordance with embodiments of the invention. Specifically, given an exemplary keeper circuit 1016 coupled to a node 1032 as shown on the left side of rule 1030, one or more additional keeper circuits (e.g., 1016′) can be coupled to node 1032 as shown on the right side of rule 1030. Therefore, the one or more additional keeper circuits (e.g., 1016′) coupled to node 1032 can each be referred to as a redundant element.

FIG. 10E illustrates an exemplary gate redundancy replacement rule 1040 in accordance with embodiments of the invention. Specifically, given an exemplary keeper circuit that includes inverter circuits 1042 and 1044 coupled to a node 1046 as shown on the left side of rule 1040, one or more additional keeper circuits (e.g., 1016) can be coupled to a node 1048 as shown on the right side of rule 1040. It is appreciated that the right side circuit of rule 1040 can be implemented as shown on the rightmost side of rule 1040, wherein keeper circuit 1016 can include inverter circuits 1012 and 1012′, but is not limited to such. Therefore, the one or more additional keeper circuits (e.g., 1016) coupled to node 1048 can each be referred to as a redundant element.

FIG. 10F illustrates an exemplary gate redundancy replacement rule 1050 in accordance with embodiments of the invention. Specifically, rule 1050 establishes that given a number N of one or more inverter circuits (e.g., 1052) coupled in series between nodes 1054 and 1056 as shown on the top part of rule 1050, a number M of one or more inverter circuits (e.g., 1058) coupled in series can be coupled in parallel with the N inverter circuits (e.g., 1052) if N and M are either both an even number, or both an odd number as shown on the bottom part of rule 1050. Therefore, rule 1050 establishes that any number of redundant elements (e.g., inverter circuits) can be added to the N and M segments of its circuit on the bottom part of rule 1050, as long as N and M are either both an even number, or both an odd number.

FIG. 10G illustrates an exemplary gate redundancy replacement rule 1060 in accordance with embodiments of the invention. Specifically, given exemplary outputs 1062 and 1064 that are the inverse of the other as shown on the left side of rule 1060, an odd number N of inverter circuits (e.g., 1066) and/or an odd number M of inverter circuits (e.g., 1068) can be coupled in series between outputs 1062 and 1064 as shown on the right side of rule 1060. Therefore, the odd number N of inverter circuits (e.g., 1066) and/or the odd number M of inverter circuits (e.g., 1068) coupled in series between outputs 1062 and 1064 can each be referred to as a redundant element. Note that one or more inverter circuits can be coupled in parallel with inverter circuits 1066 and/or 1068 between outputs 1062 and 1064.

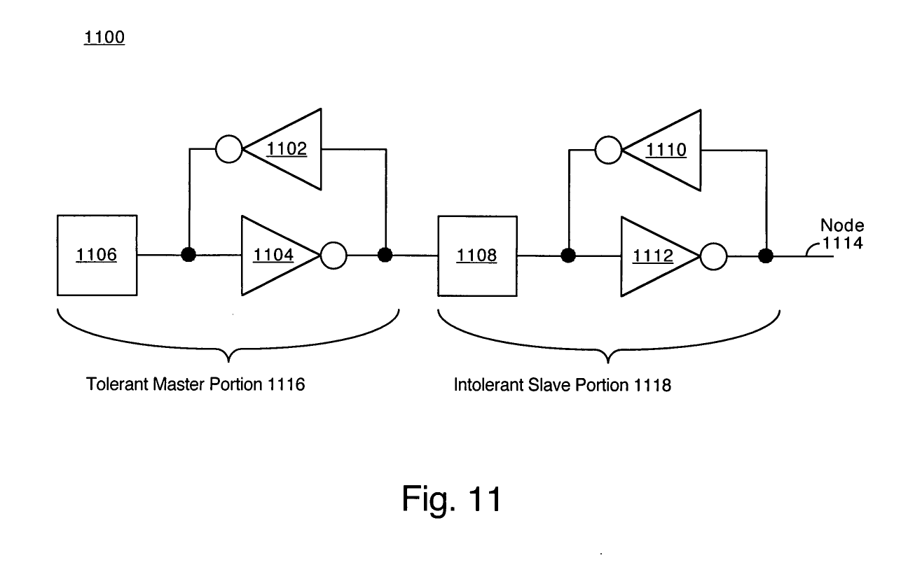

FIG. 11 is a diagram of an exemplary latch circuit 1100 having a tolerant master portion 1116 and an intolerant slave portion 1118 in accordance with embodiment of the invention. It is appreciated that circuit 1100 is designed such that if it stops operating for some reason, the tolerant master portion 1016 can save the electrical operating state. As such, when circuit 1100 recovers from the operating stoppage, the electrical state can be recovered from the tolerant master portion 1116 as opposed to the intolerant slave portion 1118 that is not designed to hold an electrical operating state. Therefore, in accordance with one embodiment, it is noted that one or more redundant elements, as described herein, can be added or included as part of the tolerant master portion circuitry 1116 while no redundant elements are added to the intolerant slave portion circuitry 1118.

Circuit 1100 can include latch circuitry 1106 having an output that can be coupled to the input of inverter circuit 1104 and the output of inverter circuit 1102. The output of inverter 1104 can be coupled to the input of inverter 1102 and an input of latch circuitry 1108. An output of latch circuitry 1108 can be coupled to the input of inverter circuit 1112 and the output of inverter circuit 1110. The output of inverter 1112 can be coupled to the input of inverter 1110 and a node 1114.

The foregoing descriptions of specific embodiments in accordance with the invention have been presented for purposes of illustration and description. They are not intended to be exhaustive or to limit the invention to the precise forms disclosed, and obviously many modifications and variations are possible in light of the above teaching. The invention can be construed according to the Claims and their equivalents.

What is claimed is:

1. A storage element circuit comprising:
a first inversion element coupled to a redundant element; and
a second inversion element coupled to said first inversion element.

2. The storage element circuit of claim 1, wherein said redundant element comprises a transistor.

3. The storage element circuit of claim 1, wherein said redundant element comprises a third inversion element.

4. The storage element circuit of claim 3, wherein said redundant element is coupled in series with said first inversion element and said second inversion element.

5. The storage element circuit of claim 3, wherein said redundant element is coupled in parallel with said first inversion element and said second inversion element.

6. The storage element circuit of claim 1, wherein said first inversion element and said redundant element are a stacked inverter.

7. The storage element circuit of claim 1, wherein said redundant element comprises a series of inversion elements.

8. The storage element circuit of claim 1, wherein said redundant element comprises parallel coupled inversion elements.

9. The storage element circuit of claim 8, wherein said parallel coupled inversion elements comprises parallel coupled stacked inverters.

10. A method comprising:
utilizing a first inversion element to generate a storage element circuit;
coupling a redundant element to said first inversion element to generate said storage element circuit; and
coupling a second inversion element to said first inversion element to generate said storage element circuit.

11. The method as described in claim 10, wherein said redundant element comprises a switching element.

12. The method as described in claim 10, wherein said redundant element comprises a third inversion element.

13. The method as described in claim 10, wherein said redundant element coupled in series to said first inversion element and said second inversion element.

14. The method as described in claim 10, wherein said redundant element coupled in parallel to said first inversion element and said second inversion element.

15. The method as described in claim 10, wherein said first inversion element and said redundant element are a stacked inverter.

16. A static storage element circuit comprising:
a first inverter circuit coupled to a redundant element; and
a second inverter circuit coupled to said first inverter circuit.

17. The static storage element circuit of claim 16, wherein said redundant element comprises a transistor.

18. The static storage element circuit of claim 16, wherein said first inverter circuit and said redundant element comprise a stacked inverter circuit.

19. The static storage element circuit of claim 16, wherein said redundant element comprises series coupled inverter circuits.

20. The static storage element circuit of claim 16, wherein said redundant element comprises parallel coupled inverter circuits.
